(19) United States
(12) Patent Application Publication
(10) Pub. No.: US 2018/0224499 A1
(43) Pub. Date: Aug. 9, 2018

(54) RELIABILITY MANAGEMENT SYSTEM AND OPERATION THEREOF

(71) Applicants: Semiconductor Manufacturing International (Beijing) Corporation, Beijing (CN); Semiconductor Manufacturing International (Shanghai) Corporation, Shanghai (CN)

(72) Inventors: Gang NIU, Shanghai (CN); Xiaodong ZHAO, Shanghai (CN); Jianshu YU, Shanghai (CN)

(21) Appl. No.: 15/888,503

(22) Filed: Feb. 5, 2018

(30) Foreign Application Priority Data
Feb. 7, 2017 (CN) 201710066299.4

(51) Int. Cl. G01R 31/28; G01R 31/26; H01L 21/67; H01L 21/66

(52) U.S. Cl. CPC G01R 31/2855; G01R 31/2894; H01L 22/20; H01L 21/67288; H01L 22/14; G01R 31/2601

(57) ABSTRACT

A reliability management system and its operation method is presented. The reliability management system comprises instructions stored in a computer-readable non-transitory storage medium, with said instructions executable by one or more hardware processors communicating with the storage medium, the system comprises a reliability manager and a Reliability Test Requestor (RTR). The reliability manager receives a test equipment request from the RTR and sends corresponding test equipment information to the RTR. The RTR sends a test equipment request to the reliability manager based on product information of a test product it receives, and receives test data from a corresponding test equipment according to the test equipment information received from the reliability manager. The RTR also processes the test data to generate a test report, and determines whether the test product passed a reliability test based on the test report. This inventive concept realizes an automatic management on reliability tests.

### CROSS-REFERENCE TO RELATED APPLICATION

This application claims priority to and benefit of Chinese Patent Application No. 201710066299.4 filed on Feb. 7, 2017, which is incorporated herein by reference in its entirety.

### BACKGROUND

### (a) Field of the Invention

This inventive concept relates generally to semiconductor technology, and more specifically, to a reliability management system and its operation method.

### (b) Description of the Related Art

Conventionally, reliability data from a reliability test of a semiconductor product are stored in Qualify documents in a Document Management System (DMS), and only a document serial number and a status of the reliability test (whether the test is completed or not) are recorded. These data are inadequate either for Reliability Engineering (RE) or for effective client communication. Additionally, in conventional methods, many RE data are stored in public folders without a systematic management. As a result, over a period of time RE data become difficult to be found, if they can be found at all, and the difficulty in obtaining reliability data and RE data results in an inaccurate reliability evaluation of a product.

### SUMMARY

The inventive concept is based on investigation of the issues in conventional techniques and proposes an innovative solution that remedies at least one issue in conventional techniques.

This inventive concept first presents a reliability management system comprising instructions stored in a computer-readable non-transitory storage medium, wherein said instructions are executable by one or more hardware processors communicating with the storage medium, the system comprising:

a reliability manager; and

a Reliability Test Requestor (RTR), wherein the reliability manager receives a test equipment request from the RTR and sends corresponding test equipment information to the RTR, and wherein the RTR receives product information of a test product and sends a test equipment request to the reliability manager based on the product information, and receives test data from a corresponding test equipment according to the test equipment information from the reliability manager, the RTR also processes the test data to generate a test report, and determines whether the test product has passed a reliability test based on the test report.

Additionally, the aforementioned system may further comprise:

a Side Braze Assembler (SBA), wherein the SBA receives an assembly data request from the RTR and sends corresponding assembly data to the RTR,

and wherein the RTR chooses a test type according to the product information, and sends an assembly data request to the SBA if the test type is Packaging Level Reliability (PLR) or ProDuct Reliability (PDR).

Additionally, the aforementioned system may further comprise:

a Reliability Index (RI), wherein the RI generates reliability index parameters of the test product according to the test report, wherein the reliability index parameters include a reliability score and a reliability life,

and wherein the RTR sends the test report to the RI after the test product passes the reliability test.

Additionally, in the aforementioned system, the RTR may operate in one of several modes including quality inspection mode, evaluation mode, monitor mode, and process adjustment mode,

wherein in quality inspection mode, the RTR receives the test reports for all the test types and sends the test reports to a file management system and/or the RI,

wherein in evaluation mode, the RTR receives the test report for at least one test type and sends the test report to the RI,

wherein in monitor mode, the RTR receives the test report for at least one test type at a fixed interval and sends the test report to the RI,

and wherein in process adjustment mode, the RTR receives the test report for at least one test type after a manufacture process has been changed.

Additionally, in the aforementioned system, the RTR may assign a priority level to the test product, and send the priority level of the test product to the reliability manager, and the reliability manager may generate a test time for the test product according to its priority level and send the test time to the RTR.

Additionally, in the aforementioned system, the reliability manager may send an alarm signal and lock down the test equipment when a malfunction signal is detected, and unlock the test equipment after it receives a repair report of the test equipment.

Additionally, the aforementioned system may further comprise:

a Reliability Test Key (RTK) designer, wherein the RTK designer generates a chip layout map based on product information of a wafer, computes a test location of the test product based on the chip layout map, and sends the test location to the RTR, wherein the test product is on the wafer,

and wherein the RTR conducts a test on the test product on the test location using a corresponding test equipment.

Additionally, in the aforementioned system, the RTR may send an alarm signal when the test data are outside an alarm range.

Additionally, the aforementioned system may further comprise:

an administrative authorizer, wherein the administrative authorizer accepts an access request, and verifies whether the access request meets an authorization requirement, if it does, the administrative authorizer allows operations including an operation to log in to the reliability management system and an operation to review or edit the test report.

This inventive concept further presents a reliability management method, comprising:

receiving product information of a test product;

receiving corresponding test equipment information based on the product information;

receiving test data from a corresponding test equipment according to the test equipment information;

processing the test data to generate a test report; and

determining whether the test product has passed a reliability test.

Additionally, the aforementioned method may further comprise:

choosing a test type based on the product information before receiving test equipment information, and receiving assembly data if the test type is Package Level Reliability (PLR) or ProDuct Reliability (PDR).

Additionally, the aforementioned method may further comprise:

generating reliability index parameters of the test product according to the test report, wherein the reliability index parameters include a reliability score and a reliability life.

Additionally, the aforementioned method may further comprise:

in quality inspection mode, obtaining and uploading the test reports for all the test types;

in evaluation mode, obtaining and uploading the test report for at least one test type;

in monitor mode, obtaining and uploading the test report for at least one test type at a fixed interval; and

in process adjustment mode, obtaining the test report for at least one test type after a manufacture process has been changed.

Additionally, in the aforementioned method, receiving corresponding test equipment information based on the product information may comprise:

assigning a priority level to the test product; and

obtaining a test time of the test product according to its priority level.

Additionally, the aforementioned method may further comprise:

sending an alarm signal and locks down the test equipment when a malfunction signal is received, and unlocking the test equipment after a repair has been performed on the test equipment.

Additionally, the aforementioned method may further comprise:

obtaining wafer product information of a wafer, wherein the test product is on the wafer;

generating a chip layout map according to the wafer product information; and

obtaining a test location of the test product according to the chip layout map before receiving product information of the test product.

Additionally, the aforementioned method may further comprise: sending an alarm signal when processing the test data if the test data are outside an alarm range.

Additionally, the aforementioned method may further comprise:

accepting an access request; and

verifying whether the access request satisfies an authorization requirement, and allowing operations including an operation to log in to the reliability management system and an operation to review or edit the test report if the access request satisfies the authorization requirement.

### BRIEF DESCRIPTION OF THE DRAWINGS

The accompanying drawings, which are incorporated herein and constitute a part of the specification, illustrate different embodiments of the inventive concept and, together with the detailed description, serve to describe more clearly the inventive concept.

FIG. 1 shows a diagram illustrating a structural connection of a reliability management system in accordance with one embodiment of this inventive concept.

FIG. 2 shows a diagram illustrating a structural connection of a reliability management system in accordance with another embodiment of this inventive concept.

FIG. 3 shows a flowchart illustrating a reliability management system working in quality inspection mode in accordance with one embodiment of this inventive concept.

FIG. 4 shows a flowchart illustrating a reliability management system working in evaluation mode in accordance with one embodiment of this inventive concept.

FIG. 5 shows a flowchart illustrating a reliability management system working in monitor mode in accordance with one embodiment of this inventive concept.

FIG. 6 shows a flowchart illustrating a reliability management system working in process adjustment mode in accordance with one embodiment of this inventive concept.

FIG. 7 shows a flowchart illustrating a Reliability Test Requestor (RTR) in a reliability management system receiving a test location of a test product in accordance with one embodiment of this inventive concept.

FIG. 8 shows a flowchart illustrating a reliability management method in accordance with one embodiment of this inventive concept.

### DETAILED DESCRIPTION OF THE EMBODIMENTS

Example embodiments of the inventive concept are described with reference to the accompanying drawings. As those skilled in the art would realize, the described embodiments may be modified in various ways without departing from the spirit or scope of the inventive concept. Embodiments may be practiced without some or all of these specified details. Well known process steps and/or structures may not be described in detail, in the interest of clarity.

The drawings and descriptions are illustrative and not restrictive. Like reference numerals may designate like (e.g., analogous or identical) elements in the specification. To the extent possible, any repetitive description will be minimized.

Relative sizes and thicknesses of elements shown in the drawings are chosen to facilitate description and understanding, without limiting the inventive concept. In the drawings, the thicknesses of some layers, films, panels, regions, etc., may be exaggerated for clarity.

Embodiments in the figures may represent idealized illustrations. Variations from the shapes illustrated may be possible, for example due to manufacturing techniques and/or tolerances. Thus, the example embodiments shall not be construed as limited to the shapes or regions illustrated herein but are to include deviations in the shapes. For example, an etched region illustrated as a rectangle may have rounded or curved features. The shapes and regions illustrated in the figures are illustrative and shall not limit the scope of the embodiments.

Although the terms “first,” “second,” etc. may be used herein to describe various elements, these elements shall not be limited by these terms. These terms may be used to distinguish one element from another element. Thus, a first element discussed below may be termed a second element without departing from the teachings of the present inventive concept. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

If a first element (such as a layer, film, region, or substrate) is referred to as being “on,” “neighboring,” “connected to,” or “coupled with” a second element, then the first element can be directly on, directly neighboring, directly connected to or directly coupled with the second element, or an intervening element may also be present between the first element and the second element. If a first element is referred to as being “directly on,” “directly neighboring,” “directly connected to,” or “directly coupled with” a second element, then no intended intervening element (except environmental elements such as air) may also be present between the first element and the second element.

Spatially relative terms, such as “beneath,” “below,” “lower,” “above,” “upper,” and the like, may be used herein for ease of description to describe one element or feature's spatial relationship to another element(s) or feature(s) as illustrated in the figures. It will be understood that the spatially relative terms may encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientation), and the spatially relative descriptors used herein shall be interpreted accordingly.

The terminology used herein is for the purpose of describing particular embodiments and is not intended to limit the inventive concept. As used herein, singular forms, “a,” “an,” and “the” may indicate plural forms as well, unless the context clearly indicates otherwise. The terms “includes” and/or “including,” when used in this specification, may specify the presence of stated features, integers, steps, operations, elements, and/or components, but may not preclude the presence or addition of one or more other features, integers, steps, operations, elements, components, and/or groups.

Unless otherwise defined, terms (including technical and scientific terms) used herein have the same meanings as what is commonly understood by one of ordinary skill in the art related to this field. Terms, such as those defined in commonly used dictionaries, shall be interpreted as having meanings that are consistent with their meanings in the context of the relevant art and shall not be interpreted in an idealized or overly formal sense unless expressly so defined herein.

The term “connect” may mean “electrically connect.” The term “insulate” may mean “electrically insulate.”

Unless explicitly described to the contrary, the word “comprise” and variations such as “comprises,” “comprising,” “include,” or “including” may imply the inclusion of stated elements but not the exclusion of other elements.

Various embodiments, including methods and techniques, are described in this disclosure. Embodiments of the inventive concept may also cover an article of manufacture that includes a non-transitory computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the inventive concept may also cover apparatuses for practicing embodiments of the inventive concept. Such apparatus may include circuits, dedicated and/or programmable, to carry out operations pertaining to embodiments of the inventive concept. Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to embodiments of the inventive concept.

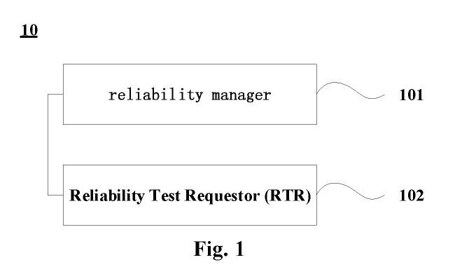

FIG. 1 shows a diagram illustrating a structural connection of a reliability management system in accordance with one embodiment of this inventive concept. Referring to FIG. 1, the reliability management system 10 may comprise instructions stored in a computer-readable non-transitory storage medium, with said instructions executable by one or more hardware processors communicating with the storage medium, the system may comprise a reliability manager 101 and a Reliability Test Requestor (RTR) 102.

The reliability manager 101 receives a test equipment request from the RTR 102 and sends corresponding test equipment information to the RTR 102. The test equipment information may include a serial number and a test time of the test equipment.

The RTR 102 sends a test equipment request to the reliability manager 101 based on product information of a test product it receives, which includes a product code or other information that can be acquired from other existing systems or from manual input. The RTR 102 receives test equipment information from the reliability manager 101, receives test data from a corresponding test equipment according to the test equipment information, and processes the test data to generate a test report that may include parameters such as a tolerable voltage, a tolerable temperature, and a tolerable film thickness of the test product, and determines whether the test product has passed the reliability test based on the test report.

In this embodiment, based on the product information it receives, the reliability management system automatically retrieves a test equipment to conduct a test on a test product to generate test data, it then processes the test data to generate a test report and determines whether the test product has passed the reliability test based on the test report. This embodiment realizes a fully automatic reliability management.

In one embodiment, the RTR 102 may assign a priority level to a test product and send the priority level to the reliability manager 101, the reliability manager 101 then generates a test time to the test product according to its priority level and sends the test time to the RTR 102. For example, after the product information of a test product is received, the reliability management system checks the reliability manager 101 for available time, and arranges the test times for all the test products according to their priority levels. Here, the test time of a test product includes a start time of the test and a duration of the test.

For example, a rule the reliability manager 101 may use to arrange a test time for a test product according to its priority level may be: if the priority level is high, the test will be arranged as an emergency event immediately after the current test, all the succeeding tests will be accordingly postponed, and a notification of this arrangement will be sent to an operator; if the priority level is medium, the test will be arranged after all the tests with high priority level; and if the priority level is low, the test will be arranged at the end of all the existing tests in the queue. To remedy a limitation that a low priority test may need to wait a long time before it can be conducted, the reliability management system may record a waiting time of a test, if the waiting time of a test is longer than a threshold (e.g., one week), the reliability management system may check the test equipment in other facilities and, if there is an available, more recent test time, automatically notify its administrator for assistance.

In one embodiment, the reliability manager 101 may send an alarm signal and lock down the test equipment if a malfunction signal in the test equipment is received. After a repair has been successfully conducted on the test equipment and the reliability manager 101 receives a repair report, the test equipment will be unlocked. In this embodiment, the reliability manager 101 monitors the working condition of the test equipment at a pre-determined interval, if a malfunction signal is received, the reliability manager 101 sends an alarm signal, locks down the test equipment and notifies the repair personnel, after a repair has been successfully conducted and the reliability manager 101 receives a repair report, the reliability manager 101 verifies that the repair is completed and then unlocks the test equipment. This embodiment realizes an automatic monitor on the test equipment, and facilitates a prompt repair in case any problem happened.

In some embodiments, the reliability manager 101 provides test equipment information on all the test equipment and records an occupation rate for each test equipment, which helps to better arrange a test time for a test product. Additionally, the reliability manager 101 may build an accessories/supplies database that records basic information about the accessories/supplies, including their inventory volumes, prices, suppliers, minimum required stock, to-be-tested substrates and the status of a test card. Additionally, the accessories/supplies data base may also record borrow/return information of the accessories/supplies.

The reliability manager 101 of this inventive concept also tracks the status of a test and automatically sends a notification upon its completion. It manages the system automatically and therefore requires little human involvement.

In one embodiment, when the test data (such as voltage or temperature) are outside an alarm range, which means the test product has a defect, the RTR 102 sends an alarm signal (e.g., to an alarm equipment).

Given a collection of test equipment and a time window, the RTR 102 of this inventive concept can compute statistic information of these test equipment during the time window. It may also automatically generate a data chart for the statistic information that can be exported for further analysis.

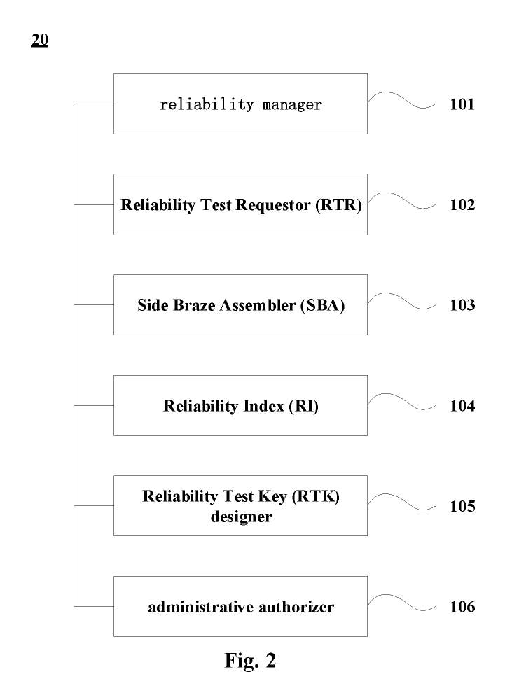

FIG. 2 shows a diagram illustrating a structural connection of a reliability management system in accordance with another embodiment of this inventive concept. Referring to FIG. 2, the reliability management system 20 comprises a reliability manager 101 and a RTR 102.

Referring to FIG. 2, in one embodiment, the reliability management system 20 may further comprise a Side Braze Assembler (SBA) 103. The SBA 103 receives an assembly data request from the RTR 102 and sends corresponding assembly data to the RTR 102. The RTR 102 may choose a test type according to the product information, if the test type is Packaging Level Reliability (PLR) or ProDuct Reliability (PDR), the assembly data request will be sent to the SBA 103; but if the test type is Wafer Level Reliability (WLR), no assembly data request will be sent to the SBA 103.

In some embodiments, the SBA 103 might work as the following. An applicant of the test first manually enters product information of a test product and submits an assembly application form, these information are verified against the information the SBA 103 automatically acquired and, if no problem found, the assembly application will be accepted. Upon approval from a supervisor, the assembly process information, including a stage of the assembly, an identifier of the equipment and a duration of the assembly, are sent to the SBA 103. After all the test processes are completed, the event is closed, and an automatic notification will be sent to the applicant. The SBA 103 receives a yield of the test product and compares it with a threshold (e.g., 95%). If the received yield is larger than the threshold, the process is completed; otherwise, a notification requesting further review will be sent to a supervisor.

Referring to FIG. 2, in one embodiment, the reliability management system 20 may further comprise a Reliability Index (RI) 104. The RI 104 generates reliability index parameters of the test product according to the test report, which may include a reliability score and a reliability life. The RTR 102 sends the test report to the RI 104 after the test product passes the reliability test.

For example, after the RI 104 receives a test report from the RTR 102, it computes a reliability score based on a relationship between the parameters in the test report (which may be a tolerable voltage, a tolerable temperature, and a tolerable film thickness of the test product) and the reference parameters, the RI 104 also computes a reliability life using a given algorithm based on the test report. The algorithm for reliability life could be any well-known algorithm and is not described here. The reliability score and the reliability life are saved in a database or a data sheet.

The reliability score and the reliability life provide quantitative evaluations on the reliability of a product on different operation environments and therefore provide valuable reliability information of a product, and the reliability life of a product can be computed for different working conditions, such as in different voltages, temperatures, equipment sizes, according to client's requirement.

In this embodiment, the RI 104 automatically computes the reliability index parameters for each test product, which helps to quickly identify a project with potential reliability issue. Additionally, the reliability index parameters are generated automatically, therefore it is more accurate than manually-computed data and the work load of a human operator is substantially reduced.

The RI 104 of this inventive concept can also utilize data from other system to automatically compute relevant parameters and automatically sort out the test products that meet a given criterion.

Referring to FIG. 2, in one embodiment, the reliability management system 20 may further comprise a Reliability Test Key (RTK) designer 105. The RTK designer 105 generates a chip layout map based on wafer product information of a wafer, then generates a test location of the test product (the test product is on the wafer) based on the chip layout map, and sends the test location to the RTR102, which then conducts a test on the test product on the test location using a corresponding test equipment.

For example, after the RTK designer 105 receives wafer product information, it verifies the correctness of these information (e.g., whether there is an alarm signal during the manufacturing process of the wafer and whether there is any issue in the product report of the wafer). If the wafer product information is correct, a chip layout map is generated based on the wafer product information, and a test location of the test product is generated based on the chip layout map. This allows the test to be conducted only on one particular location (the test location), instead of on the entire chip layout map, and thus simplifies the test process. After the RTK designer 105 receives the test location, it sends the test location to the RTR 102, which allows the RTR 102 to conduct the test on the test location with the corresponding test equipment. For example, the RTR 102 may send the test location to the Side Braze Assembler (SBA) 103, which generates a location map for each chip on the wafer, an assembly map, and a location map of furnace location. These maps are sent back to the RTR 102 as assembly data for the reliability test.

In some embodiments, the RTK designer 105 may also send the chip layout map to a human inspector to verify its correctness. If the chip layout map is verified to be correct, the RTK designer 105 generates the test location of the test product; otherwise, a new chip layout map is required.

The RTK designer 105 of this inventive concept provides a clear description of the chip layout map, it also conducts multiple self-checks for potential errors and to enforce design rules. The results of these checks are recorded for future reference and will be made available for human inspection.

Referring to FIG. 2, in one embodiment, the reliability management system 20 may further comprise an administrative authorizer 106. The administrative authorizer 106 accepts an access request from a user, and verifies whether the access request meets an authorization requirement. If it does, the administrative authorizer 106 allows the user to conduct corresponding operations including an operation to log in to the reliability management system and an operation to review or edit various data sheets (e.g., the data sheets in the test report or in the product information). For example, when the access request is a login request, the user will provide a username/password combination, if the combination is verified to be correct by the administrative authorizer 106, the user is allowed to log in. The administrative authorizer 106 may also be used to verify other operation privileges, such as a privilege to review or edit a test report or a privilege to update background information. The privileges that the administrative authorizer 106 may control are not limited herein.

In some embodiments, when a data sheet is updated (e.g., a new Quality report is inserted), the reliability management system will automatically assign a flag to such an event. Different events might be assigned different flags, and only a user with a corresponding privilege can edit the content of the data sheet with a particular flag.

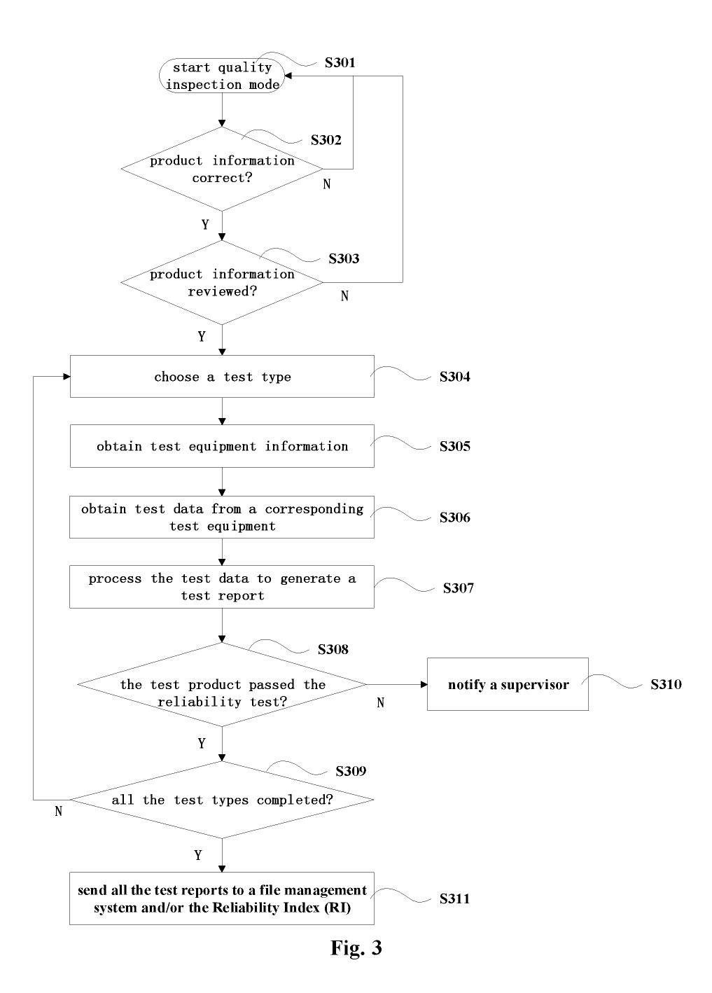

In one embodiment, the RTR 102 may work in different modes, including quality inspection mode, evaluation mode, monitor mode, and process adjustment mode. For example, in quality inspection mode, the RTR 102 receives the test reports for all the test types and sends the test reports to a file management system (not shown in FIG. 2) and/or the RI 104. In evaluation mode 104, the RTR 102 receives a test report for at least one test type based on a test requirement and sends that test report to the RI 104. In monitor mode, the RTR 102 receives a test report for at least one test type at a fixed interval and sends the test report to the RI 104. In process adjustment mode, the RTR 102 receives a test report for at least one test type after a manufacture process has been changed. The operations under these modes are described below in reference to FIGS. 3, 4, 5, and 6.

FIG. 3 shows a flowchart illustrating a reliability management system working in quality inspection mode in accordance with one embodiment of this inventive concept.

In step S301, quality inspection mode starts.

In step S302, the correctness of product information is verified. This includes checking whether there is an alarm signal during the manufacturing process of the test product and whether there is any issue in a product report. If the product information is correct (no alarm signal and no issue in the product report), the process enters step S303. Otherwise, the process returns to step S301. For example, the product information may be obtained from a Manufacturing Execution System (MES) and/or a Peripheral Interface Data Bus (PIDB) connecting to the RTR 102, or from manual input.

In step S303, it is verified that the product information in the RTR 102 has been reviewed by all the managing engineers. If all the managing engineers have reviewed and approved the product information, the process enters step S304; otherwise the process returns to step S301. This step ensures all the managing engineers are aware of the test.

In step S304, a test type is chosen. In an embodiment of this inventive concept, the test types may include PLR, PDR, and WLR. If the test type is PLR or PDR, the RTR 102 sends an assembly data request to the SBA 103 and receives assembly data from the SBA 103, if the test type is WLR, the RTR 102 does not send an assembly data request to the SBA 103, and no assembly is conducted on the test product.

In step S305, the test equipment information is obtained. For example, the RTR 102 may receive the test equipment information from the reliability manager 101, and the test equipment information may include a serial number and an occupation rate of the test equipment, and a test time of the test product.

In step S306, test data is obtained from a corresponding test equipment. In this step, the RTR 102 connects to a corresponding test equipment according to the test equipment information, and obtains the test data during the process the test equipment conducting a test on the test product.

In step S307, the test data is processed to generate a test report. In some embodiments, the RTR 102 will send out an alarm signal if the test data are outside an alarm range.

In step S308, it is determined whether the test product has passed the reliability test based on the test report. For example, this process may involve comparing the data in the test report with standard data. If the data in the test report match the standard data, the test product has passed the reliability test and the process enters step S309. Otherwise, the process enters step S310.

In step S309, it is determined whether the reliability tests of all the test types have been completed. If not (for example, if the test for PLR test type is completed, but the tests for PDR and WLR test types are not completed yet), the process goes back to step S304 to complete the tests for the remaining test types. If all the test types have been completed, the process enters step S311.

In step S310, the process sends a notification to a supervisor. That is, if a test product fails to pass the reliability test, a notification is sent to the supervisor. In some embodiments, a report may also be sent to a Failure Analysis (FA) system to further analyze the cause of the failure.

In step S311, the process sends all the test reports to a file management system and/or the RI 104. In some embodiments, the test reports may also be sent to other parts or modules (such as an online module for computing a reliability life), or to update a data sheet of the passed test products.

In this embodiment, when a new product is to be tested for reliability, the RTR 102 may conduct the reliability test in quality inspection mode and, if the new product passed the test, its information will be imported into a reliability management system, which could be a conventional reliability management system or the reliability management system of this inventive concept.

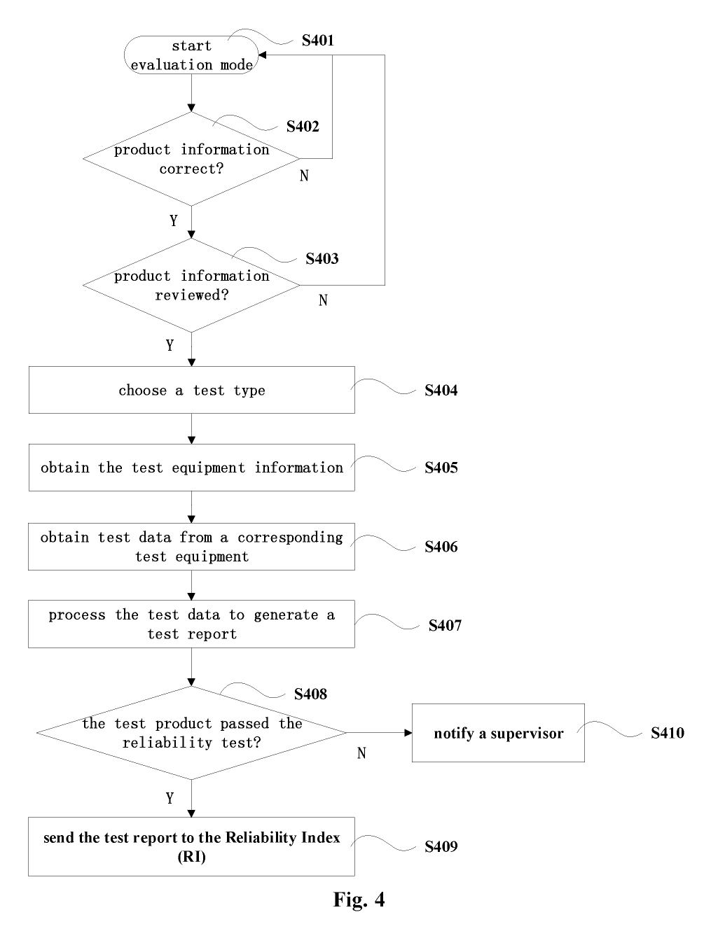

FIG. 4 shows a flowchart illustrating a reliability management system working in evaluation mode in accordance with one embodiment of this inventive concept.

In step S401, evaluation mode starts.

In step S402, the correctness of product information is verified. This includes checking whether there is an alarm signal during the manufacturing process of the test product and whether there is any issue in a product report. If the product information is correct (no alarm signal and no issue in the product report), the process enters step S403; otherwise, the process returns to step S401 repeats. For example, the product information may be obtained from a Manufacturing Execution System (MES) and/or a Peripheral Interface Data Bus (PIDB) connecting to the RTR 102, or from manual input.

In step S403, it is verified that the product information in the RTR 102 has been reviewed by all the managing engineers. If all the managing engineers have reviewed and approved the product information, the process enters step S404; otherwise the process returns to step S401.

In step S404, a test type is chosen. If the test type is PLR or PDR, the RTR 102 sends an assembly data request to the SBA 103 and receives assembly data from the SBA 103, if the test type is WLR, the RTR 102 does not send an assembly data request to the SBA 103, and no assembly is conducted on the test product.

In step S405, the test equipment information is obtained. For example, the RTR 102 may receive the test equipment information from the reliability manager 101, and the test equipment information may include a serial number and an occupation rate of the test equipment, and a test time of the test product.

In step S406, test data is obtained from a corresponding test equipment. In this step, the RTR 102 connects to a corresponding test equipment according to the test equipment information, and obtains the test data during the process the test equipment conducting a test on the test product.

In step S407, the test data is processed to generate a test report. In some embodiments, the RTR 102 will send out an alarm signal if the test data are outside an alarm range.

In step S408, the process determines whether the test product passed the reliability test based on the test report. For example, this process may involve comparing the data in the test report with standard data. If the data in the test report match the standard data, the test product passed the reliability test and the process enters step S409. Otherwise the process enters step S410.

In step S409, the test report is sent to the RI 104.

In step S410, a notification is sent to a supervisor. That is, if a test product fails to pass the reliability test, a notification is generated and sent to the supervisor. In some embodiments, a report may also be sent to a Failure Analysis (FA) system to further analyze the cause of the failure.

In this embodiment, when an existing product is to be tested for reliability, the test can be done in evaluation mode, and a test report will be generated for the test conducted in at least one test type.

The process of evaluation mode in many parts is similar to quality inspection mode, therefore if a new product has passed a test under evaluation mode, it may also be imported into existing management systems, as if it has passed a test under quality inspection mode.

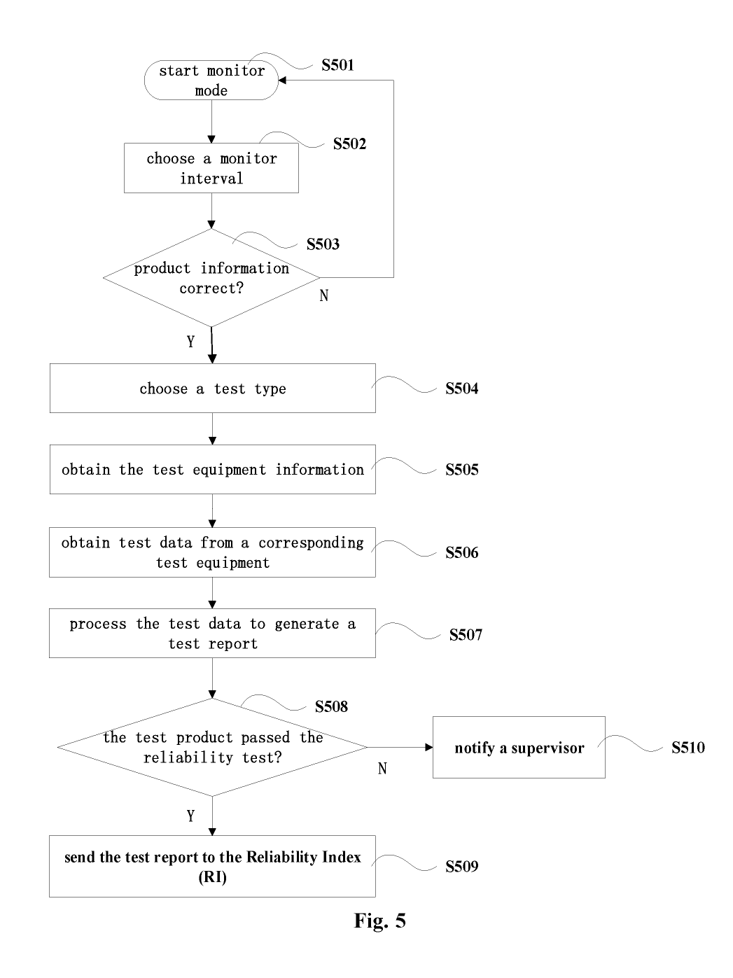

FIG. 5 shows a flowchart illustrating a reliability management system working in monitor mode in accordance with one embodiment of this inventive concept.

In step S501, monitor mode starts.

In step S502, a monitor interval is chosen, which could be one year, one quarter or one month.

In step S503, the correctness of product information is verified. This includes checking whether there is an alarm signal during the manufacturing process of a test product and whether there is any issue in the product report. If the product information is correct (no alarm signal and no issue in the product report), the process enters step S504. Otherwise, the process returns to step S501. For example, the product information may be obtained from a Manufacturing Execution System (MES) and/or a Peripheral Interface Data Bus (PIDB) connecting to the RTR 102, or from manual input.

In step S504, a test type is chosen. If the test type is PLR or PDR, the RTR 102 sends an assembly data request to the SBA 103 and receives assembly data from the SBA 103, if the test type is WLR, the RTR 102 does not send an assembly data request to the SBA 103, and no assembly is conducted on the test product.

In step S505, the test equipment information is obtained. For example, the RTR 102 may receive the test equipment information from the reliability manager 101, and the test equipment information may include a serial number and an occupation rate of the test equipment, and a test time of the test product.

In step S506, test data is obtained from a corresponding test equipment. In this step, the RTR 102 connects to a corresponding test equipment according to the test equipment information, and obtains the test data during the process the test equipment conducting a test on the test product.

In step S507, process the test data to generate a test report. In some embodiments, the RTR 102 will send out an alarm signal if the test data are outside an alarm range.

In step S508, the process determines whether the test product has passed the reliability test based on the test report. For example, this process may involve comparing the data in the test report with standard data. If the data in the test report match the standard data, the test product has passed the reliability test and the process enters step S509. Otherwise, the process enters step S510.

In step S509, the test report is sent to the RI 104.

In step S510, a notification is sent to a supervisor. That is, if a test product fails to pass the reliability test, a notification is generated and sent to the supervisor. In some embodiments, a report may also be sent to a Failure Analysis (FA) system to further analyze the cause of the failure.

In this embodiment, monitor mode can be used to periodically conduct a test on a product to obtain its reliability information. In monitor mode, a trend map may be established to record the progress of the reliability parameters of the test product, and an alarm range may be automatically set by the system to catch a defective product. This allows a prompt identification of the reliability issue in the test products, thus improves the operation efficiency and lowers the risk of a missed defective in the production line.

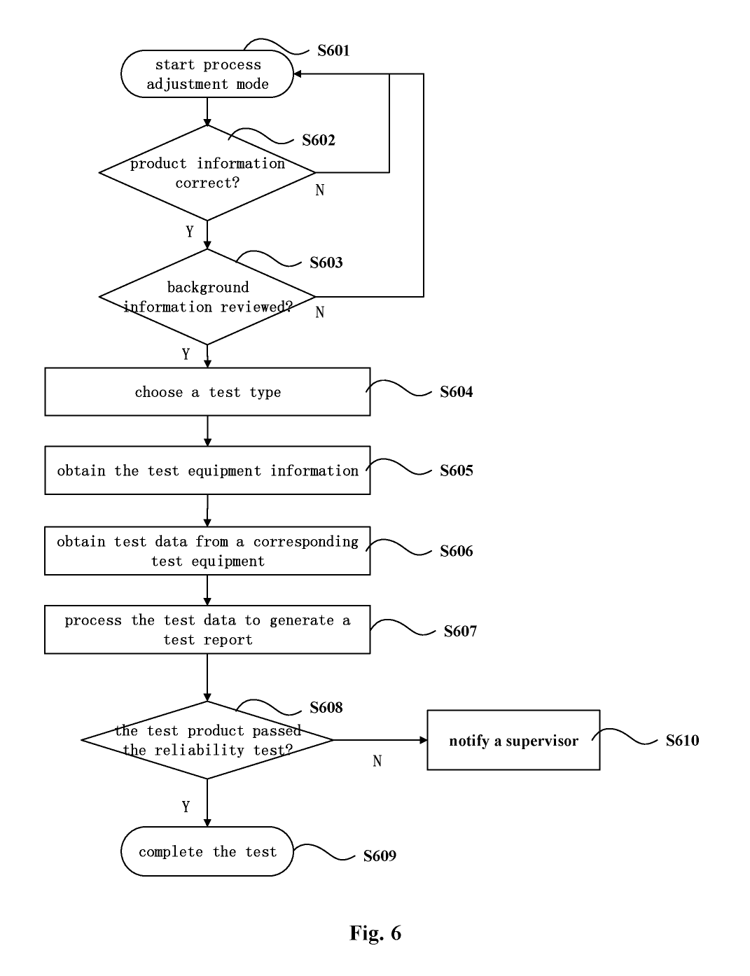

FIG. 6 shows a flowchart illustrating a reliability management system working in process adjustment mode in accordance with one embodiment of this inventive concept.

In step S601, process adjustment mode starts.

In step S602, the correctness of a product information is verified. This includes checking whether there is an alarm signal during the manufacturing process of the test product and whether there is any issue in a product report. If the product information is correct (no alarm signal and no issue in the product report), the process enters 5504. Otherwise, the process returns to step S501. For example, the product information may be obtained from a Manufacturing Execution System (MES) and/or a Peripheral Interface Data Bus (PIDB) connecting to the RTR 102, or from manual input.

In step S603, it is verified that background information of a test product in the RTR 102 has been reviewed by managing engineers. The background information may include the product information and existing test reports on the test product. If all the managing engineers have reviewed and approved the background information, the process enters step S604. Otherwise, the process returns to step S601.

In step S604, a test type is chosen. If the test type is PLR or PDR, the RTR 102 sends an assembly data request to the SBA 103 and receives assembly data from the SBA 103. If the test type is WLR, the RTR 102 does not send an assembly data request to the SBA 103, and no assembly is conducted on the test product.

In step S605, the test equipment information is obtained. For example, the RTR 102 may receive the test equipment information from the reliability manager 101, and the test equipment information may include a serial number and an occupation rate of the test equipment, and a test time of a test product.

In step S606, test data from a corresponding test equipment is obtained. In this step, the RTR 102 connects to a corresponding test equipment according to the test equipment information, and obtains the test data during the process the test equipment conducting a test on the test product.

In step S607, the test data is processed to generate a test report. In some embodiments, the RTR 102 will send out an alarm signal if the test data are outside an alarm range.

In step S608, the process determines whether the test product passed the reliability test based on the test report. For example, this process may involve comparing the data in the test report with standard data. If the data in the test report match the standard data, the test product has passed the reliability test and the process enters step S609. Otherwise, the process enters step S610.

In step S609, the test is completed.

In step S610, a notification is sent to a supervisor. That is, if a test product fails to pass the reliability test, a notification is generated and sent to the supervisor. In some embodiments, a report may also be sent to a Failure Analysis (FA) system to further analyze the cause of failure.

In this embodiment, process adjustment mode can be used to conduct a reliability test on a test product after a manufacture process has been changed. This allows a swift change of the manufacture process without losing the reliability information of the test product.

FIG. 7 shows a flowchart illustrating a RTR in a reliability management system receiving a test location of a test product in accordance with one embodiment of this inventive concept.

In step S701, wafer product information of a wafer is obtained. Wafer product information includes information such as a size and a serial number of a wafer product, and may be manually inputted.

In step S702, a chip layout map is generated based on the wafer information.

In step S703, a test location of the test product is obtained based on the chip layout map. In the embodiments of this inventive concept, the test product may be a device or a unit on the wafer.

In step S704, the test location is sent to the RTR 102.

In this embodiment, the RTK designer 105 obtains a test location based on the chip layout map that could be either from external input or generated by itself, and sends the test location to the RTR 102.

As described above, this inventive concept provides a reliability management system that evaluates the reliability and potential risk for both a new product and a product that is already in mass production, this reliability management system can provide a reliability assessment for a product under different working conditions and identify potential reliability issue at an early stage. This system provides an assessment of the maturity of a technique/product, which is an essential ingredient for a company to make sound business decisions on its technique/product. The information this system provides can provide a marketing team a quantitative description on the reliability of a technique/product and help the marketing team to properly position the technique/product in the market. It also helps engineers and technicians to promptly catch a potential reliability issue at an early stage of the production without excessive disruption to existing production.

The reliability management system of this inventive concept can also be connected to other existing systems and therefore require little extra expense to be integrated into existing systems.

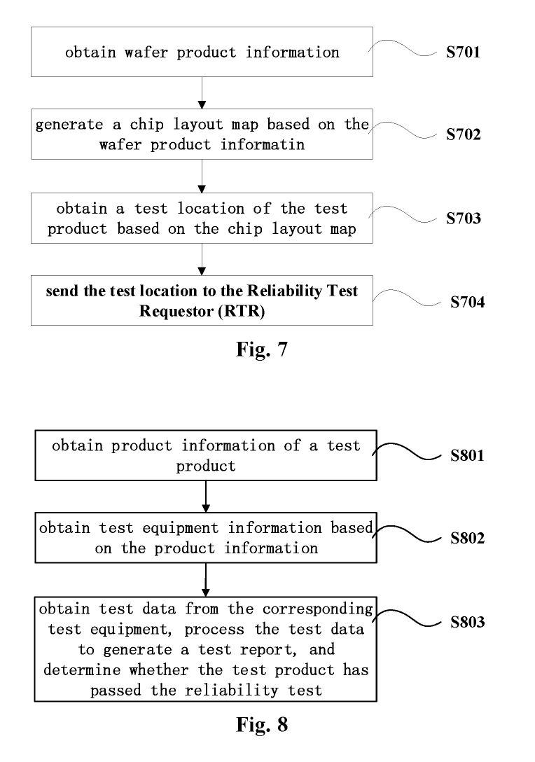

FIG. 8 shows a flowchart illustrating a reliability management method in accordance with one embodiment of this inventive concept.

In step S801, product information of a test product is obtained.

In step S802, corresponding test equipment information is obtained, based on the product information. In this step, each test product corresponds to a test equipment, so each product information has corresponding test equipment information. The test equipment information may include a serial number and a test time of the test equipment. In one embodiment, this step may also include selecting a priority level for the test product and obtaining a test time based on the priority level.

In step S803, test data is obtained from the corresponding test equipment based on the test equipment information, process the test data to generate a test report, and determine whether the test product has passed the reliability test based on the test report. In one embodiment, when processing the test data, the reliability management system will send out an alarm signal when the test data are outside an alarm range.

This embodiment provides a reliability management method. In this method, based on the product information of a test product, a test equipment is automatically utilized to conduct a test, test data are generated from the corresponding test equipment, a test report is generated from the test data, and the pass/fail of the reliability test is determined by the test reported. The reliability management system of this inventive concept thus realizes an automatic reliability management.

In one embodiment, before step S802, the reliability management method may further comprise: selecting a test type according to the product information. If the test type is PLR or PDR, assembly data is obtained, if the test type is WLR, no assembly is conducted on the test product.

In one embodiment, the reliability management method may further comprise: obtaining reliability parameters of the test product based on the test report. The reliability parameters include a reliability score and a reliability life.

In one embodiment, the reliability management method may further comprise: in quality inspection mode, obtaining and uploading test reports for all the test types. In another embodiment, the reliability management method may further comprise: in evaluation mode, obtaining and uploading a test report for at least one test type. In another embodiment, the reliability management method may further comprise: in monitor mode, obtaining and uploading a test report for at least one test type in a fixed interval. In another embodiment, the reliability management method may further comprise: in process adjustment mode, obtaining a test report for at least one test type after a manufacture process has been changed.

In one embodiment, the reliability management method may further comprise: sending an alarm signal and locking down the test equipment when a malfunction signal is received, and releasing the lock-down on the test equipment after a repair has been successfully conducted on the test equipment.

In one embodiment, the reliability management method may further comprise: before step S801, receiving an access request; verifying whether the access request meets an authorization requirement, and, if it does, granting a privilege to corresponding operations, which include an operation to log in to the reliability management system and an operation to review or edit a test report.

This inventive concept provides a complete process to handle the reliability test request and reduces missed defect (false negative) on the reliability test. The test data of the reliability test are saved and can be used for a later risk assessment for special product or device to lower the defect rate.

This concludes the description of a reliability management system and its operation method in accordance with one or more embodiments of this inventive concept. For purposes of conciseness and convenience, some components or procedures that are well known to one of ordinary skill in the art in this field are omitted. These omissions, however, do not prevent one of ordinary skill in the art in this field to make and use the inventive concept herein disclosed.

While this inventive concept has been described in terms of several embodiments, there are alterations, permutations, and equivalents, which fall within the scope of this disclosure. It shall also be noted that there are alternative ways of implementing the methods and/or apparatuses of the inventive concept. Furthermore, embodiments may find utility in other applications. It is therefore intended that the claims be interpreted as including all such alterations, permutations, and equivalents. The abstract section is provided herein for convenience and, due to word count limitation, is accordingly written for reading convenience and shall not be employed to limit the scope of the claims.

What is claimed is:

1. A reliability management system comprising instructions stored in a computer-readable non-transitory storage medium, wherein said instructions are executable by one or more hardware processors communicating with the storage medium, the system comprising:
a reliability manager; and
a Reliability Test Requestor (RTR), wherein the reliability manager receives a test equipment request from the RTR and sends corresponding test equipment information to the RTR, and wherein the RTR receives product information of a test product and sends a test equipment request to the reliability manager based on the product information, and receives test data from a corresponding test equipment according to the test equipment information from the reliability manager, the RTR also processes the test data to generate a test report, and determines whether the test product passed a reliability test based on the test report.

2. The reliability management system of claim 1, further comprising:
a Side Braze Assembler (SBA), wherein the SBA receives an assembly data request from the RTR and sends corresponding assembly data to the RTR,
and wherein the RTR chooses a test type according to the product information, and sends an assembly data request to the SBA if the test type is Packaging Level Reliability (PLR) or ProDuct Reliability (PDR).

3. The reliability management system of claim 2, further comprising:
a Reliability Index (RI), wherein the RI generates reliability index parameters of the test product according to the test report, wherein the reliability index parameters include a reliability score and a reliability life,
and wherein the RTR sends the test report to the RI after the test product passes the reliability test.

4. The reliability management system of claim 3, wherein the RTR operates in one of several modes including quality inspection mode, evaluation mode, monitor mode, and process adjustment mode,
wherein in quality inspection mode, the RTR receives the test reports for all the test types and sends the test reports to a file management system and/or the RI,
wherein in evaluation mode, the RTR receives the test report for at least one test type and sends the test report to the RI,
wherein in monitor mode, the RTR receives the test report for at least one test type at a fixed interval and sends the test report to the RI,
and wherein in process adjustment mode, the RTR receives the test report for at least one test type after a manufacture process has been changed.

5. The reliability management system of claim 1, wherein the RTR assigns a priority level to the test product, and sends the priority level of the test product to the reliability manager,
and wherein the reliability manager generates a test time for the test product according to its priority level and sends the test time to the RTR.

6. The reliability management system of claim 1, wherein the reliability manager sends an alarm signal and locks down the test equipment when a malfunction signal is detected, and unlocks the test equipment after it receives a repair report of the test equipment.

7. The reliability management system of claim 1, further comprising:
a Reliability Test Key (RTK) designer, wherein the RTK designer generates a chip layout map based on product information of a wafer, computes a test location of the test product based on the chip layout map, and sends the test location to the RTR, wherein the test product is on the wafer,
and wherein the RTR conducts a test on the test product on the test location using a corresponding test equipment.

8. The reliability management system of claim 1, wherein the RTR sends an alarm signal when the test data are outside an alarm range.

9. The reliability management system of claim 1, further comprising:
an administrative authorizer, wherein the administrative authorizer accepts an access request, and verifies whether the access request meets an authorization requirement, if it does, the administrative authorizer allows operations including an operation to log in to the reliability management system and an operation to review or edit the test report.

10. A reliability management method, comprising:
receiving product information of a test product;
receiving corresponding test equipment information based on the product information;
receiving test data from a corresponding test equipment according to the test equipment information;
processing the test data to generate a test report; and
determining whether the test product has passed a reliability test.

11. The method of claim 10, further comprising:
choosing a test type based on the product information before receiving test equipment information, and receiving assembly data if the test type is Package Level Reliability (PLR) or ProDuct Reliability (PDR).

12. The method of claim 11, further comprising:
generating reliability index parameters of the test product according to the test report, wherein the reliability index parameters include a reliability score and a reliability life.

13. The method of claim 12, further comprising:
in quality inspection mode, obtaining and uploading the test reports for all the test types;
in evaluation mode, obtaining and uploading the test report for at least one test type;
in monitor mode, obtaining and uploading the test report for at least one test type at a fixed interval; and
in process adjustment mode, obtaining the test report for at least one test type after a manufacture process has been changed.

14. The method of claim 10, wherein receiving corresponding test equipment information based on the product information comprises:
assigning a priority level to the test product; and
obtaining a test time of the test product according to its priority level.

15. The method of claim 10, further comprising:
sending an alarm signal and locks down the test equipment when a malfunction signal is received, and unlocking the test equipment after a repair has been performed on the test equipment.

16. The method of claim 10, further comprising:
obtaining wafer product information of a wafer, wherein the test product is on the wafer;
generating a chip layout map according to the wafer product information; and
obtaining a test location of the test product according to the chip layout map before receiving product information of the test product.

17. The method of claim 10, further comprising:
sending an alarm signal when processing the test data if the test data are outside an alarm range.

18. The method of claim 10, further comprising:
accepting an access request; and
verifying whether the access request satisfies an authorization requirement, and allowing operations including an operation to log in to the reliability management system and an operation to review or edit the test report if the access request satisfies the authorization requirement.
